(19) United States
(12) Patent Application Publication
(10) Pub. No.: US 2025/0040057 A1
(43) Pub. Date: Jan. 30, 2025

(54) METHOD FOR PRODUCING AN ANGULAR POSITION SENSOR

(71) Applicant: Baumueller Nuernberg GmbH, Nuernberg (DE)

(72) Inventor: Johannes PIRLING, Bad Gandersheim (DE)

(73) Assignee: Baumueller Nuernberg GmbH, Nuernberg (DE)

(21) Appl. No.: 18/908,738

(22) Filed: Oct. 7, 2024

Related U.S. Application Data
(63) Continuation of application No. PCT/EP2023/056617, filed on Mar. 15, 2023.

(30) Foreign Application Priority Data
Apr. 7, 2022 (DE) 10 2022 203 538.0

(51) Int. Cl. H05K 3/30; G01B 7/30

(52) U.S. Cl. CPC H05K 3/303; G01B 7/30; H05K 2203/0195

(57) ABSTRACT

A method for producing an angular position sensor, in which a Hall sensor fastened to a printed circuit board is inserted into a receptacle of an assembly tool. A housing is arranged around the printed circuit board, wherein the housing is aligned with the assembly tool, and the printed circuit board is fastened to the housing. The invention also relates to an assembly tool and an angular position sensor.

This nonprovisional application is a continuation of International Application No. PCT/EP2023/056617, which was filed on Mar. 15, 2023, and which claims priority to German Patent Application No. 10 2022 203 538.0, which was filed in Germany on Apr. 7, 2022, and which are both herein incorporated by reference.

### BACKGROUND OF THE INVENTION

### Field of the Invention

The invention relates to a method for producing an angular position sensor, to an assembly tool, and to an angular position sensor. The angular position sensor in each case includes a circuit board with a Hall sensor.

### Description of the Background Art

In machines driven by an electric motor, for example machine tools, for precise operation of the machine it is necessary to know the present phase position of the electric motor. Thus, for example, the precise metering of plastic for an injection molding machine, or the correct pressure in an offset printing machine that is fed with paper rolls, is possible only when the present angle of the rotor with respect to the stator and/or the present rotational speed of the electric motor are/is known. Therefore, an angular position sensor is generally flange-mounted on a shaft of the rotor.

The angular position sensor is designed as a resolver, for example, so that a comparatively precise measurement of the particular present angle of the rotor with respect to the stator is possible. However, production costs for such a resolver are relatively high. In a less expensive variant, the angular position sensor includes a Hall sensor that interacts with a magnet that is rotatably fastened to the rotor so that the angle may be detected. Two Hall sensors that are offset relative to one another by 90° with respect to the rotational axis of the rotor are generally provided. Thus, when the rotor rotates, a data series referred to as a sine track is detected by one of the Hall sensors, and a data series referred to as a cosine track is detected by the other Hall sensor. If the two sensors are not precisely aligned with one another with respect to the rotational axis, the data do not strictly correspond to an actual sine or cosine, for which reason an angular position determined in this way is not exact. Therefore, a comparatively time-consuming calibration of the angular position sensor is initially required.

The two Hall sensors, for example, have a discrete design with respect to one another. However, for simplified assembly, chips are also known that include the two Hall sensors. The two Hall sensors are precisely aligned with one another on the substrate of the chip. However, the circuit boards to which the chip is generally affixed must be precisely positioned within a housing of the angular position sensor. For this purpose, the housing usually has a multipart design, so that it is possible to finely adjust the circuit board with respect to the individual components of the housing.

### SUMMARY OF THE INVENTION

It is therefore an object of the invention to provide a particularly suitable method for producing an angular position sensor, a particularly suitable assembly tool, and a particularly suitable angular position sensor, wherein production costs for the angular position sensor and/or the reject rate are/is advantageously reduced, and the quality and/or robustness are/is suitably increased.

The method can be used for the production of an angular position sensor. The angular position sensor is in particular a sensor for detecting a rotation angle or a change thereof on a shaft relative to a stationary part. For this purpose, the angular position sensor in particular has a shaft which, for example, is rotatably supported by means of a bearing. Alternatively, the bearing is not an integral part of the angular position sensor, and the shaft is, for example, directly fastened to a rotor of a further machine whose rotation angle is to be determined. The rotor is advantageously rotatably supported by means of a bearing of the further machine.

The shaft can be likewise an integral part of the further machine. In all variants, in particular the stationary part in each case is an integral part of the angular position sensor. In the installed state, the stationary part is advantageously fastened to the further machine.

The further machine is advantageously an electric machine, for example a generator or preferably an electric motor. The angular position sensor or at least the possible stationary part is preferably fastened to an end shield of the electric machine. The electric machine is, for example, an integral part of a motor vehicle, such as a commercial vehicle or a passenger car. In a further alternative, the motor vehicle is, for example, a construction vehicle or an agricultural implement. However, the electric machine is particularly preferably an integral part of an industrial facility and thus has a stationary design. During operation using the electric machine, for example a workpiece is machined, moved, and/or created. For this purpose, the electric machine carries, or at least is able to carry, in particular a maximum electric current of greater than 1000 A, 2000 A, 3000 A, or 4000 A.

In the method, a Hall sensor can be inserted into a receptacle of an assembly tool. The Hall sensor is fastened to a circuit board and in particular is designed as a chip, or the chip includes the Hall sensor. In particular, the Hall sensor is designed as an integrated circuit (IC). For example, the Hall sensor is a surface-mount device (SMD), or is fastened to the circuit board by push-through installation, for example. The circuit board is advantageously made of a glass fiber-reinforced epoxy resin, and has multiple strip conductors and/or solder pads, to at least some of which the Hall sensor is soldered or at least fastened. In particular, the possible chip includes a further Hall sensor, the orientations of the two Hall sensors differing from one another, and the Hall sensors being rotated by 90°, for example, relative to an axis that is perpendicular to the circuit board.

In particular, the Hall sensor or at least the chip can be situated concentrically with respect to a rotational axis of the angular position sensor, which in particular is perpendicular to the circuit board having an essentially circular design, for example. The rotational axis preferably extends through the center of the circuit board.

In summary, the receptacle which specifies the position of the Hall sensor is provided using the assembly tool. In particular, a clearance fit between the Hall sensor and the receptacle is thus provided, wherein, for example, the receptacle corresponds exactly to the outer dimensions of the Hall sensor or of the chip that includes the Hall sensor. Alternatively, for example an overlength that is advantageously less than 0.1 mm is present. Regions of the receptacle are also present which have a greater distance from the Hall sensor/chip, thus facilitating insertion. In particular, the Hall sensor or the chip providing the Hall sensor is essentially cuboidal, the receptacle likewise being cuboidal. The corners of the receptacle are preferably flared out so that insertion is facilitated. Comparatively exact positioning of the Hall sensor within the receptacle is still made possible by means of the lateral edges of the receptacle. The outer edges of the receptacle are preferably beveled, which further facilitates insertion of the Hall sensor into the receptacle.

For example, the circuit board may be already manufactured at the start of the method. Alternatively, the method comprises a further, preceding work step in which the circuit board is manufactured, in particular the Hall sensor also being fastened to the circuit board, preferably by soldering.

A housing can be subsequently arranged around the circuit board. In particular, the housing is pulled over the circuit board, so that the circuit board is at least partially enclosed by the housing. The circuit board is preferably completely enclosed by use of the assembly tool and the housing. The housing is aligned with the assembly tool, i.e., using the assembly tool, for which purpose in particular an alignment device of the assembly tool is used. The circuit board is subsequently fastened to the housing. In other words, the position of the circuit board relative to the housing is stabilized, the two positions relative to one another being specified by the assembly tool. For example, the fastening takes place using a further component, in particular a fastening means, or in an integrally bonded manner by use of an adhesive, for example. Alternatively, the housing and/or the circuit board are/is melted, at least in part, resulting in an integrally bonded connection between them.

Thus, due to the method it is necessary only that the assembly tool is manufactured with comparatively high precision. However, it is at least necessary for the position of the receptacle, with respect to the component of the assembly tool used for the alignment, to be produced with comparatively small tolerances, whereas the remaining components of the assembly tool may likewise have increased manufacturing tolerances. The Hall sensor still has a comparatively precise alignment with respect to the housing, and any tolerances in the fastening of the Hall sensor to the circuit board and/or manufacturing tolerances of the circuit board do not result in a change in the positioning of the Hall sensor relative to the housing.

The housing can be, for example, made of an aluminum, such as pure aluminum or an aluminum alloy, using a pressure die-casting process, for example. Production costs for the housing are thus reduced. In the installed state, the housing is generally fastened to a further component of a possible (further) machine whose angular position is to be detected using the angular position sensor, for example a possible end shield. Since the housing is aligned comparatively precisely with respect to the possible machine, the Hall transmitter is also aligned comparatively precisely with respect to the possible machine. Thus, the quality in determining the angular position using the angular position sensor is improved, and calibration is essentially not necessary. The production time is thus shortened, and consequently the production costs are also reduced. In addition, comparatively high manufacturing tolerances may be selected for the circuit board and the fastening of the Hall sensor to the circuit board, for which reason production costs are likewise reduced. Accurate positioning of the Hall sensor with respect to the housing is still always provided by means of the assembly tool, so that the reject rate is reduced. Furthermore, it is possible to manufacture the housing to be comparatively robust, and it is not necessary to provide an option for fine adjustment. The robustness is thus increased.

For example, the assembly tool can be made of a stainless steel, preferably by milling. Comparatively precise manufacture of the assembly tool is thus made possible. Although the production costs and the production time for the assembly tool are increased, it is necessary to manufacture the assembly tool only once, and it may be used to produce a relatively large number of angular position sensors.

For example, the housing has a peg, which for the alignment is inserted into a corresponding borehole in the assembly tool. However, an outer contour of the housing is particularly preferably aligned with an edge of the assembly tool. In other words, the edge acts as an alignment device for the housing. The position of the housing is determined by its outer contour, so that even the housing may otherwise be manufactured with comparatively large manufacturing tolerances, wherein the position of the outer edge of the housing with respect to the Hall sensor is predetermined. The assembly of the angular position sensor on the possible (further) machine takes place by positioning using the outer edge of the housing, since it is accessible from the outside. Thus, by use of the outer edge of the housing, the Hall sensor is also comparatively precisely aligned with respect to the further machine. No further components are necessary for aligning the housing, so that the weight of the housing and also production costs are reduced.

For example, the housing can have a cuboidal design or particularly preferably a cup-shaped design. In particular, the edge of the assembly tool is circular, and by means of the assembly tool in particular a cup-shaped depression is provided as an alignment device, whose boundary forms the edge and into which the housing is inserted. The transverse orientation of the housing with respect to the Hall sensor is thus specified by the assembly tool; however, it is possible to rotate the housing relative to the Hall sensor into a certain position, wherein the axis about which the housing can be rotated during the assembly corresponds in particular to the rotational axis of the angular position sensor, which preferably passes through the Hall sensor. A clearance fit is preferably created between the edge, i.e., in particular of the possible cup-shaped depression, and the outer contour, so that the housing may be rotated relative to the assembly tool, for which reason a desired orientation may be selected.

For example, the circuit board can be stabilized solely via the receptacle until the former is fastened to the housing. However, the assembly tool particularly preferably has additional pins on which the circuit board is placed. The pins are preferably spaced apart with respect to the receptacle and/or one another. The pins prevent tilting of the circuit board, thus facilitating insertion of the Hall sensor into the receptacle.

For example, the pins can have a blunt design, and the circuit board merely rests loosely on the pins. However, the circuit board particularly preferably has corresponding holes through which a portion of the pins, which in particular have a stepped design on the end, are guided. The circuit board thus rests on the step, with the free end of the pins protruding through the circuit board. In this way, the position of the circuit board is likewise partly specified by means of the pins. The pins are used solely for coarse alignment of the circuit board, so that in particular the insertion of the Hall sensor into the receptacle is facilitated. In particular, there is a comparatively large amount of play between the pins and the holes, so that the alignment is facilitated by the receptacle. For example, the pins are made of the same material as the receptacle, and the assembly tool is one piece, for example.

However, the pins are particularly preferably made of a separate material, and are for example fastened to a base body of the assembly tool, which provides the receptacle as well as the part for aligning the housing. The pins may thus be manufactured with increased manufacturing tolerances, thus further reducing production costs. In addition, it is possible to replace the pins, for example when they are damaged. Furthermore, it is thus necessary only to manufacture the base body with comparatively small manufacturing tolerances, which on the one hand facilitates the production and on the other hand reduces the production costs for the assembly tool.

For example, an inner wall of the housing is smooth and corresponds in particular to the outer contour of the housing. Production is thus simplified and the weight of the housing is reduced. However, the inner wall of the housing preferably has an inwardly projecting thickened area. In the region of the thickened area, the inner wall of the housing is thus displaced into the interior, and the housing has an increased wall thickness in the region of the thickened area, for example. The circuit board has a corresponding notch whose contour corresponds in particular to the contour of the thickened area. The notch is suitably rounded, and has a semicircular design, for example. In particular, for arranging the housing around the circuit board, the notch is moved along the thickened area, preferably creating a clearance fit between the housing and the circuit board. The circuit board is moved, relative to the housing, in particular along a direction that is parallel to the rotational axis of the angular position sensor. Due to the thickened area and the notch, an orientation of the circuit board relative to the housing is thus specified when the housing is arranged around the circuit board. The housing may thus be subsequently aligned with the assembly tool more easily and quickly.

In particular, the thickened area has a slot that is advantageously situated between the two ends of the thickened area, and that in particular is parallel to the circuit board. When the housing has been aligned with the assembly tool, the slot advantageously lies in a plane with the circuit board and is situated directly next to same. Due to the notch, a gap is provided between the slot and the remainder of the thickened area, so that the arrangement and alignment of the housing are not hindered by the circuit board.

The housing can be subsequently rotated relative to the circuit board, the rotational axis in particular corresponding to the rotational axis of the angular position sensor. As a result, the circuit board is moved into the slot in the thickened area, and the rotation is ended in particular when the circuit board rests within the thickened area. The circuit board is thus partially stabilized with respect to the housing, and fastening of the circuit board to the housing is simplified. A clearance fit is preferably created between the circuit board and the slot, so that the rotation is facilitated without the Hall sensor moving within the receptacle. In other words, the housing and the Hall sensor remain aligned with one another, even during the rotation. In particular, the distance between the slot and the circuit board is less than 0.2 mm, so that the position of the Hall sensor is also at least partially specified by the slot, but the circuit board may still be manufactured with comparatively high manufacturing tolerances. In summary, the slot specifies the position of the circuit board within the housing and thus partially supports the circuit board.

The slot is already present during the primary forming of the housing, for example. Alternatively, the slot is not milled into the thickened area until later, which takes place, for example, within the scope of the method. The housing preferably includes two such thickened areas, which are preferably offset relative to one another by an angle between 90° and 180°, and suitably by exactly 180°, with respect to the rotational axis. As a result, tilting of the circuit board relative to the housing is prevented by the two slots. Alternatively, more thickened areas are present, which in particular are arranged rotationally symmetrically with respect to the rotational axis. Tilting of the circuit board relative to the housing is thus reliably avoided. The number of thickened areas is preferably three, so that the weight of the angular position sensor is not excessively increased. Alternatively, even further thickened areas, each having the slot, are present.

The pins, which limit the rotational movement of the housing with respect to the circuit board, are preferably present. For this purpose, the pins in particular are situated in corresponding guides of the housing, which in particular are created by recesses in the inner wall of the housing. Each guide provides two stops. When the associated pin rests against the one stop, in particular insertion of the circuit board into the housing is enabled, and the housing is thus placed on the assembly tool along the pins, in parallel to the rotational axis. The rotation subsequently takes place until the pins rest against the oppositely situated stop of the particular guide. The circuit board than also rests in the slot. Thus, no special measurement or the like is necessary, even during the rotation, thus simplifying assembly.

For example, the circuit board is fixed within the slot by use of adhesive. However, the circuit board and the housing are particularly preferably screwed in using a screw. This screw is screwed in particular into the thickened area. For this purpose, the thickened area has a hollow design, in particular in the portion facing away from the assembly tool, and from this side in particular the screw is inserted into the thickened area from outside the housing. The circuit board advantageously has a corresponding hole through which the screw is guided. It is thus possible to insert the screw from the side facing away from the assembly tool, which simplifies assembly. In addition, it is thus possible to use a comparatively inexpensive assembly tool.

The screw is in particular screwed into the portion of the thickened area facing the assembly tool. For this purpose, this portion of the thickened area in particular has a corresponding female thread, or the screw has a self-tapping or self-threading design. Manufacture of the housing is simplified in this way. As a result, the circuit board is subsequently held between the screw head and the portion of the thickened area, and thus stabilized at the housing. In other words, the circuit board is clamped between the screw head and the portion of the thickened area. The two thickened areas are particularly preferably present, with a corresponding screw being associated with each of the thickened areas. The stability is thus increased.

For example, the angular position sensor additionally includes a rotor, which in particular is manufactured separately. The rotor advantageously includes a permanent magnet, which in the installed state interacts with the Hall sensor. For example, the permanent magnet is fastened on a shaft of the angular position sensor, or the shaft is formed, at least in part, by the permanent magnet. In particular, the shaft is supported so that it is rotatable about the rotational axis, for which purpose the angular position sensor advantageously includes a bearing such as a ball bearing.

The assembly tool is used to carry out a method for producing an angular position sensor. In the method, a Hall sensor that is fastened to a circuit board is inserted into a receptacle in the assembly tool. In addition, a housing is arranged around the circuit board, the housing being aligned with the assembly tool. Furthermore, the circuit board is fastened to the housing. The assembly tool is suited, in particular provided and configured, for this purpose.

The assembly tool includes the receptacle for the Hall sensor that is fastened to the circuit board, as well as an alignment device for aligning the housing. For example, the assembly tool is made in one piece from a metal, preferably a stainless steel. In particular, the assembly tool is produced by milling. It is thus possible to produce the assembly tool with comparatively small manufacturing tolerances, so that the reject rate for the angular position sensors produced using this assembly tool is reduced. In addition, robustness is increased, and the assembly tool may be used to produce numerous such angular position sensors. For example, the assembly tool, or at least a base body of the assembly tool via which the alignment device and the receptacle are provided, has a one-piece design. Comparatively precise manufacture of the assembly tool is thus possible, and subsequent alignment of the alignment device and the receptacle is not necessary. Furthermore, robustness is increased.

For example, the assembly tool additionally includes pins which in particular are inserted into corresponding boreholes in the possible base body. A press fit between the pins and the base body is suitably created so that the pins are prevented from accidentally coming loose. The pins are made from a stainless steel, for example, which increases robustness. Three such pins are preferably present, in particular arranged rotationally symmetrically with respect to the receptacle.

The alignment device of the assembly tool particularly preferably has a cup-shaped depression which in particular is provided via the (possible) base body. The border of the cup-shaped depression preferably forms an edge with which the housing may be aligned. Due to the cup-shaped depression, it is possible for the housing to rotate within the depression, and to connect to the circuit board in the manner of a bayonet lock, for example.

A dome can be situated inside the cup-shaped depression, preferably at its midpoint, the dome being suitably situated concentrically with respect to the depression. In other words, the two axes are superposed. In particular, the axis of the dome is the same as the rotational axis of the angular position sensor, provided that the latter is mounted on the assembly tool. The dome is in particular cuboidal, and the receptacle is provided using the free end of the dome. For this purpose, the free end is in particular recessed, preferably in a rectangular manner. The corners are preferably flared out so that insertion of the Hall sensor is simplified. In addition, the outwardly directed edges are preferably beveled, which further simplifies insertion of the Hall sensor.

The angular position sensor can have a one-piece cup-shaped housing which in particular is made of an aluminum. The housing is preferably produced using a pressure die-casting process. The cup-shaped housing thus has a base, and on the side opposite the base has an opening which in the installed state is preferably directed toward a possible further machine, and which is closed by a component of the possible further machines, such as an end shield. A circuit board to which a Hall sensor is fastened is situated inside the housing. The Hall sensor is suitably situated on the side of the circuit board facing away from the (cup) base.

Due to the cup-shaped housing the circuit board can be comparatively protected, and it is not necessary to join separate components to form the housing with comparatively small manufacturing tolerances. Production is thus simplified, and production costs are also reduced. In summary, it is not necessary to combine individual components to form the housing, thus reducing production costs. In addition, seal-tightness is increased. Furthermore, inventory storage is simplified, since only a single component for the housing has to be kept on hand.

In particular, the angular position sensor can also includes a rotor, which for example includes a permanent magnet that is fastened to a shaft. The shaft is situated in particular on the sides of the opening in the cup-shaped housing, and preferably protrudes partially into the housing. Compactness is thus increased.

The angular position sensor can be produced according to a method in which the Hall sensor that is fastened to the circuit board is inserted into a receptacle of an assembly tool, and a housing is arranged around the circuit board, the housing being aligned with the assembly tool. In addition, according to the method the circuit board is fastened to the housing.

The invention further relates to a machine that includes such an angular position sensor, in particular an electric machine such as an electric motor. The rotational axis of the angular position sensor is preferably the same as the rotational axis of the electric machine, and the rotor of the angular position sensor is in particular fastened to a rotor of the electric machine.

At an inner wall of the housing, the angular position sensor in particular has an inwardly projecting thickened area having a slot that is situated in parallel to the circuit board, within which the circuit board rests. Thus, the position of the circuit board is at least partially specified by the slot in the thickened area. The circuit board preferably has a notch so that it is possible to insert the circuit board into the housing, the notch being moved along the thickened area. By subsequent rotation the circuit board is inserted into the slot, in particular in the manner of a bayonet connection. As a result, it is possible to remove the circuit board from the housing by merely rotating the circuit board and the slot relative to one another, thus increasing robustness of the angular position sensor.

For example, the circuit board merely rests loosely within the slot or is fixed at that location using an adhesive, for example. However, the thickened area is particularly preferably hollow in the portion of the slot facing the base of the housing, and a screw head of a screw is accommodated by this portion of the thickened area. The screw is screwed into the remaining portion of the thickened area, so that the screw is guided through the circuit board. The screw is situated in particular in parallel to the rotational axis of the angular position sensor, and the circuit board is thus clamped between the remaining portion of the thickened area, into which the screw is screwed, and the screw head. The circuit board is thus captively fastened to the housing, it also being possible, for example, to replace the circuit board if it is damaged by the screw connection. The screw is preferably guided with overlength through a hole in the circuit board, so that the orientation of the Hall sensor with respect to the housing is not changed during the screwing operation.

The refinements and advantages explained in conjunction with the method are also analogously transferable to the assembly tool/the angular position sensor/the electric machine as well as among one another, and vice versa

Further scope of applicability of the present invention will become apparent from the detailed description given hereinafter. However, it should be understood that the detailed description and specific examples, while indicating preferred embodiments of the invention, are given by way of illustration only, since various changes and modifications within the spirit and scope of the invention will become apparent to those skilled in the art from this detailed description.

### BRIEF DESCRIPTION OF THE DRAWINGS

The present invention will become more fully understood from the detailed description given hereinbelow and the accompanying drawings which are given by way of illustration only, and thus, are not limitive of the present invention, and wherein:

FIG. 1 shows a sectional illustration of an angular position sensor along a rotational axis,

FIG. 2 shows the angular position sensor in an exploded illustration,

FIG. 3 shows a method for producing the angular position sensor,

FIG. 4 shows a perspective view of an assembly tool with a dome,

FIG. 5 shows a perspective enlarged view of the dome, by means of which a receptacle is provided,

FIG. 6 shows a circuit board of the angular position sensor,

FIG. 7 shows a perspective view of the circuit board mounted on the assembly tool,

FIG. 8 shows a perspective view of a housing of the angular position sensor, and

FIGS. 9-13 each show a perspective view of the angular position sensor in different stages of production.

### DETAILED DESCRIPTION

Mutually corresponding parts are provided with the same reference numerals in all figures.

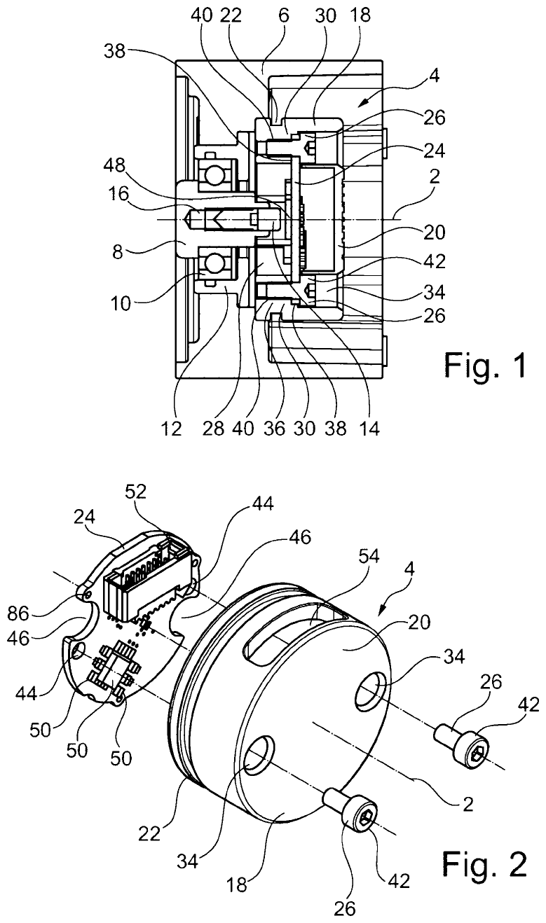

A portion of an angular position sensor 4 is illustrated in FIG. 1 in a sectional illustration along a rotational axis 2, and in FIG. 2 in an exploded illustration; the angular position sensor is fastened to an end shield 6 of an electric machine, namely, an electric motor. The angular position sensor 4 has a shaft 8 which is situated concentrically with respect to the rotational axis 2, and which by means of a ball bearing 10 is supported so that it is rotatable about the rotational axis 2. The ball bearing 10 in turn is enclosed by a hollow cylindrical retaining element 12 of the angular position sensor 4 and is partially fastened thereto. The retaining element 12 is inserted into a corresponding opening in the end shield 6, where it is fastened in a rotatably fixed manner, so that mutually corresponding structures engage with one another.

On the side opposite from the angular position sensor 4, a housing of the electric machine is fastened to the end shield 6 and is thus closed by the end shield 6. A rotor of the electric machine, which is likewise supported so that it is rotatable about the rotational axis 2 by means of bearings is accommodated by the housing. The shaft 8 is rotatably fixedly fastened to the rotor of the electric machine, and at the end facing away from the rotor a permanent magnet 14, which is manufactured in the manner of a pin, is placed in a blind hole 16 in the shaft 8 situated concentrically with respect to the rotational axis 2, and protrudes beyond same on the end side. The permanent magnet 14 is situated on the side of the end shield 6 opposite from the rotor.

In addition, a housing 18 of the angular position sensor 4, having a cup-shaped, one-piece design, is rotatably fixedly fastened to the end shield 6. The housing 18 is made of an aluminum in a pressure die-casting process, and is situated concentrically with respect to the rotational axis 2 so that a (cup) base 20 extends perpendicularly with respect to the rotational axis 2 and is situated at a distance from the end shield 6. The opening in the cup-shaped housing 18 is thus partially closed by the retaining element 2 and the end shield 6. A circumferential groove 22 with which a corresponding fastening element of the end shield 6 engages is introduced into the housing 18, namely, into a side wall, on the outside.

A circuit board 24 that is fastened to the housing 18 by means of two screws 26 is situated inside the housing 18. For this purpose, an inner wall 28 of the housing 18 has two radially inwardly projecting thickened areas 30 that are offset by 180° relative to the rotational axis 2 and that extend in parallel to the rotational axis 2. Each of the thickened areas 30 has two portions 34, 36 which are separated from one another by a respective slot 38 extending perpendicularly with respect to the rotational axis 2. The portion 34 facing the base 20 has a hollow design. The remaining portion 36, facing the end shield 6, has a female thread 40 into which the respective screw 26 is screwed, the respective screw head 42 being situated in the portion 34 facing the base 20 of the housing.

The circuit board 24 is situated in the two slots 38, and for each of the screws 26 has a corresponding hole 44 through which the particular screw 26 is guided. An overlength is present between each hole 44 and the particular screw 26, so that the circuit board 24 may be mounted in different positions with respect to the housing 18. However, in the installed state the circuit board 24 is clamped between the screw heads 42 and the remaining portions 36, so that movement of the circuit board 24 relative to the housing 18 is not possible.

Adjacent to each of the holes 44 and offset from same in the same angular direction with respect to the rotational axis 2, the circuit board 24 has a semicircular notch 46 on each edge side. The dimensions of the notches 46 in each case correspond to the outer dimensions of each of the thickened areas 30 or at least the remaining portions 36, and the notches 46 are used for assembly of the angular position sensor 4.

A Hall sensor 48 designed as a chip, namely, as an integrated circuit (IC), is fastened to the circuit board 24 on the side facing away from the base 20, and concentrically with respect to the rotational axis 2. On the side facing the base 20, further electrical and/or electronic components 50 as well as a plug 52 are fastened to the circuit board 24, the plug being electrically contacted with the electrical/electronic component 50 and with the Hall sensor 48 by strip conductors. In the installed state, the plug 52 is positioned within a plug opening 54 in the side wall of the housing 18, the plug opening being completely closed off by the plug 52. With the exception of the plug opening 54 and the openings provided by the thickened areas 30, the housing 18 has a closed design. In the installed state, all openings of the housing 18 are closed, thus preventing penetration of foreign particles or moisture into the housing 18 which could result in impaired functioning.

During operation of the electric machine, its rotor and therefore also the shaft 8 of the angular position sensor 4 are rotated about the rotational axis 2. The permanent magnet 14 is thus likewise rotated, resulting in a temporally changing magnetic field that is detected by means of the Hall sensor 48. The signals thus detected are at least partially evaluated by means of the electrical/electronic components 50 and provided to the plug 52. In the installed state, a corresponding mating plug of the electric machine is inserted into the plug 52, and control of the electric machine takes place based on the signals provided by means of the plug 52.

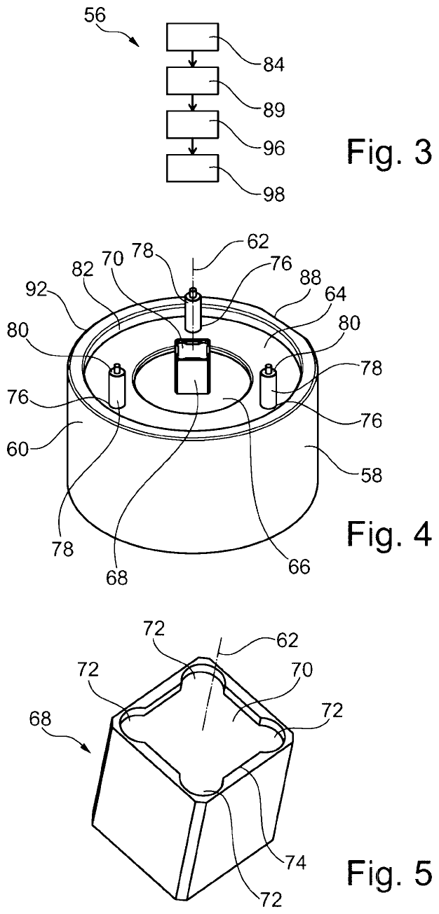

FIG. 3 illustrates a method 56 for producing the angular position sensor 4. In the method 56, an assembly tool 58 shown in a perspective view in FIG. 4 is used, the assembly tool having a cylindrical base body 60 that extends along an axis 62. During assembly, the axis 62 coincides with the rotational axis 2 of the angular position sensor 4 to be produced using the assembly tool 58.

One of the end-face sides of the base body 60 has a cup-shaped depression 64 that is concentric with respect to the axis 62. A cup-shaped further depression 66 having a reduced diameter is introduced into the depression 64. Situated within the further depression 66 and thus also within the depression 64 is a cuboidal dome 68 of the base body 60 that extends along the axis 62, illustrated in a perspective view in FIG. 5. The free end of the dome 68 facing away from the further depression 66 has a receptacle 70 which is essentially a cuboidal recess, the corners 72 being flared out so that a three-quarter circle is described by each of the corners 72. The edges 74 of the receptacle 70 are beveled, so that the receptacle 70 is slightly widened with increasing distance from the further depression 66.

The depression 64 has three boreholes 76 that are rotationally symmetrical with respect to the axis 62 and that extend along this axis, into which a respective pin 78 is inserted with a press fit, the pin likewise being parallel to the axis 62. The pins 78 are separate components from the base body 60, and are likewise made of a stainless steel. The free end of each pin 78 facing away from the base body 60 has a step 80, so that each of the pins 78 has a tapered design at the free end facing away from the base body 60. The steps 80 are situated essentially in a plane that is perpendicular to the axis 62.

The base body 60 is produced in one piece from a stainless steel by milling, with the smallest possible manufacturing tolerances being selected for production of the receptacle 70 and for the circumferential edge 82 that radially outwardly borders the depression 64 with respect to the axis 62. Since the pins 78 are produced separately from the base body 60, they do not hinder the creation of the edge 82.

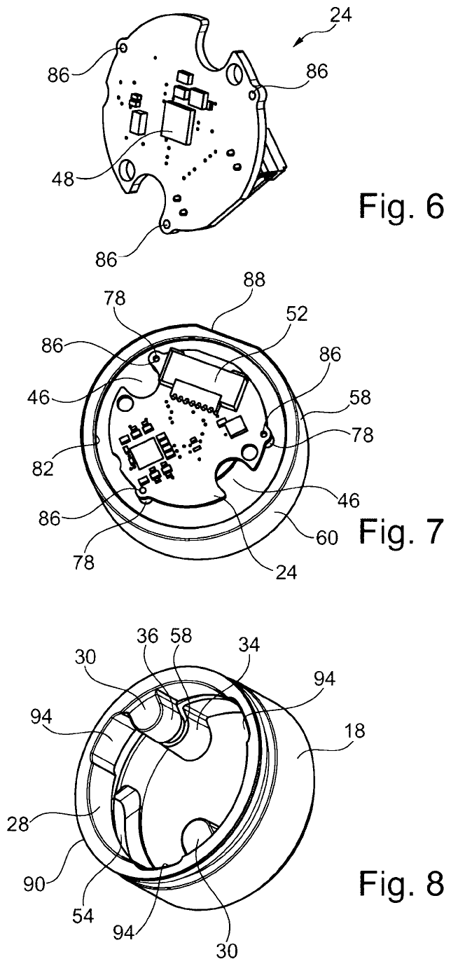

The circuit board 24 illustrated in a perspective view in FIG. 6 is mounted on the assembly tool 58 in a first work step 84, as illustrated in FIG. 7. For this purpose, the Hall sensor 48 is inserted into the receptacle 70 of the assembly tool 58. Insertion of the cuboidal Hall sensor 48 is facilitated by the beveled edges 74. Since the corners 72 are flared out, damage to the Hall sensor 48 is ruled out, even for an insertion that is initially slightly skewed. The lateral edges of the receptacle 70 are designed in such a way that when the Hall sensor 48 is laid within the receptacle 70, it rests directly against the receptacle, although comparatively simple insertion is still possible. However, the Hall sensor 48 and thus also the circuit board 24 are aligned by means of the receptacle 70. As a result, the Hall sensor 48 is situated on the axis 62 and is concentric with respect to same.

The circuit board 24 has three positioning holes 86 that are placed on the pins 78. When the Hall sensor 48 is inserted into the receptacle 70, the circuit board 24 rests on the steps 80 of the pins 78, with each pin 78, namely, the tapered portion, being guided through one of the respective positioning holes 86. A comparatively large gap is present between the pins 78 and the particular positioning hole 86, so that the circuit board 24 is oriented relative to the assembly tool 58 solely via the Hall sensor 48 and the receptacle 70, and is not hindered by the pins 78 or the positioning holes 86. However, tilting of the circuit board 24 is prevented by the pins 78. In summary, the circuit board 24 is placed on the pins 78 of the assembly tool 58.

The base body 60 has a flattened area 88 on one of the sides for facilitated positioning at the start of the insertion. The plug 52 points toward the flattened area 88 when the Hall sensor 48 is inserted into the receptacle 70.

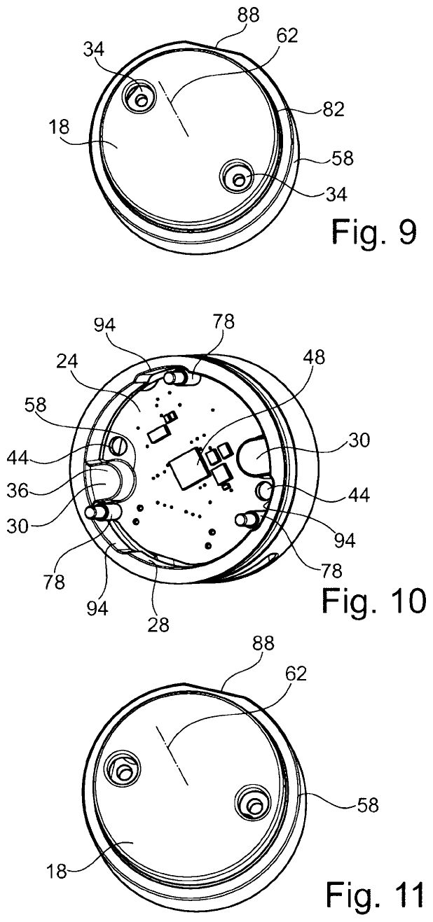

The housing 18 illustrated in a perspective view in FIG. 8 is pulled over the circuit boards 24 in a subsequent second work step 89, so that the one-piece housing 18 is arranged around the circuit board 24 as illustrated in FIG. 9. An outer contour 90 of the housing 18, which is provided in the region of the opening in the cup-shaped housing 18, rests against the edge 82 of the depression 64, so that the housing 18 is aligned with the assembly tool 58. In summary, the cup-shaped depression 64 is used as an alignment device 92 for aligning the housing 18, the outer contour 90 of the housing 18 being aligned with the edge 82 of the assembly tool 58, namely, the alignment device 92.

During the positioning of the housing 18, each of the thickened areas 30 that projects inwardly from the inner wall 28 of the housing 18 is in each case guided through one of the edge-side notches 46 in the circuit board 24. The lengths of the pins 78 and of the dome 68 are adapted so that when the circuit board 44 is placed on the pins 78 and the Hall sensor 48 is inserted into the receptacle 70, and when the housing 18 is inserted into the depression 64, the circuit board 24 is situated in a plane with the slots 58 in the thickened areas 30, as shown in FIG. 10 for the assembly tool 58, the base body 60 not being illustrated. In other words, the circuit board 24 is moved along the completely remaining portion 36 of the particular thickened areas 30. Three guides 94 are introduced into the inner wall 28, each being formed by a ridge-like reduction in the thickness of the wall of the housing 18. One of the pins 78 rests in each of the guides 94; when the housing 18 is arranged on the assembly tool 58, each pin 78 is moved parallel to the axis 62 at a tangential end of the particular guide 94, i.e., at one of the stops of the particular guide 94.

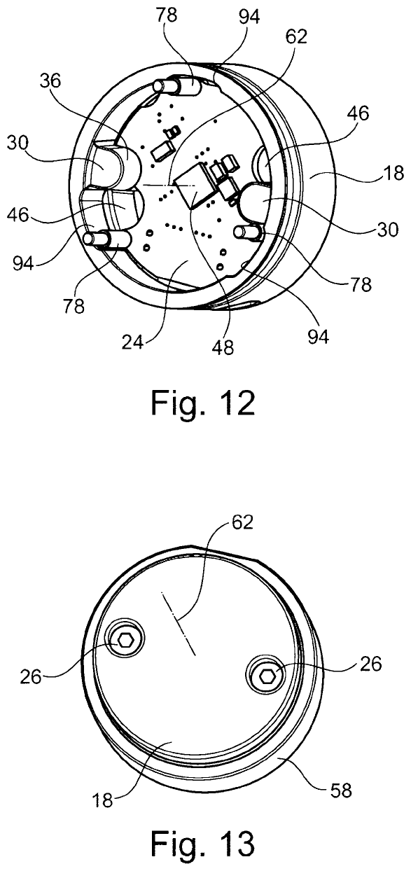

The housing 18 is rotated about the axis 62 in a subsequent third work step 96, so that the plug 52 no longer points toward the flattened area 88. Since the circuit board 24 is stabilized by the Hall sensor 48 resting in the receptacle 70 and by the pins 78 resting in the positioning holes 86, the housing 18 is rotated relative to the circuit board 24. As a result, the circuit board 24 slides into the slots 58 in the thickened areas 30 which extend parallel to the circuit board 24 and perpendicularly with respect to the axis 62. The notches 46 are subsequently tangentially offset relative to the respective associated thickened area 30 with respect to the axis 62, as shown for the assembly tool 58 in FIG. 12, the base body 60 once again not being illustrated.

The housing 18 is rotated relative to the circuit board 24 and thus also relative to the assembly tool 58 until further rotation is no longer possible due to the pins 78 resting against the oppositely situated stops of the particular guide 94. In other words, the angle by which the housing 18 is rotated relative to the circuit board 24 is specified by the guides 94 and the pins 78. After the rotation, the holes 44, which as illustrated in FIG. 10 were initially tangentially offset relative to the thickened areas 30 during insertion of the circuit board 24 into the housing 18, are situated between the two portions 34, 36 of the respective thickened area 30 in the particular slot 38.

In a subsequent fourth work step 98, one of the screws 26 is inserted in each case, from the side facing away from the assembly tool 58, into the portion 34 of the respective thickened area 30 facing the base 34 of the housing 18. Each screw 26 is guided through the hole 44 in the circuit board 24, which is appropriately positioned due to the rotation, and screwed into the respective remaining portion 36, namely, the female thread 40. The circuit board 24 is thus clamped between the remaining portion 36 of the thickened areas 30 and the particular screw head 42, and the circuit board 24 and the housing 18 are screwed in via the screws 26, so that the circuit board 24 is fastened to the housing 18 as illustrated in FIG. 13.

The method 56 is subsequently ended, and the shaft 8 and the permanent magnet 14 as well as the ball bearing 10 and the retaining elements 12 are manufactured in a separate process and fastened to the housing 18. In one alternative, these parts are installed in work steps of the method 56.

The invention is not limited to the exemplary embodiment described above. Rather, other variants of the invention may also be deduced by those skilled in the art without departing from the subject matter of the invention. In particular, all individual features described in conjunction with the exemplary embodiment may also be combined with one another in some other way without departing from the subject matter of the invention.

What is claimed is:

1. A method for producing an angular position sensor, the method comprising:
fastening a Hall sensor to a circuit board and inserting such into a receptacle of an assembly tool;
arranging a housing around the circuit board, the housing being aligned with the assembly tool; and
fastening the circuit board to the housing.

2. The method according to claim 1, wherein an outer contour of the housing is aligned with an edge of the assembly tool.

3. The method according to claim 1, wherein the circuit board is also placed on pins of the assembly tool.

4. The method according to claim 1, wherein a thickened area that projects inwardly at an inner wall of the housing is guided through an edge-side notch in the circuit board, and wherein the housing is subsequently rotated relative to the circuit board such that the circuit board rests in a slot in the thickened area that extends substantially in parallel to the circuit board.

5. The method according to claim 4, wherein the circuit board and the housing are screwed in using a screw that is screwed into the thickened area.

6. An assembly tool for carrying out the method according to claim 1, the assembly comprising: a receptacle for a Hall sensor that is fastened to a circuit board; and an alignment device to align a housing.

7. The assembly tool according to claim 6, wherein the alignment device) has a cup-shaped depression within which a dome is arranged whose free end provides the receptacle.

8. An angular position sensor comprising a circuit board that is arranged in a one-piece cup-shaped housing and to which a Hall sensor is fastened.

9. The angular position sensor according to claim 8, wherein a thickened area that protrudes inwardly at an inner wall of the housing has a slot arranged substantially in parallel to the circuit board, within which the circuit board rests.

10. The angular position sensor according to claim 9, wherein the portion of the thickened area facing the base of the housing, with respect to the slot, is hollow and accommodates a screw head of a screw that is screwed into the remaining portion of the thickened area, the circuit board being clamped between the remaining portion of the thickened area and the screw head.
